(19) United States
(12) Patent Application Publication
(10) Pub. No.: US 2026/0147207 A1
(43) Pub. Date: May 28, 2026

(54) ANTENNA ARCHITECTURES FOR TEMPLE OF AR CAPABLE WEARABLE DEVICES

(71) Applicant: Snap Inc., Santa Monica, CA (US)

(72) Inventors: Jason Heger, Louisville, CO (US); Stoyan Hristov, Gilroy, CA (US); Ugur Olgun, Marina Del Rey, CA (US)

(21) Appl. No.: 18/958,944

(22) Filed: Nov. 25, 2024

Related U.S. Application Data
(60) Provisional application No. 63/603,371, filed on Nov. 28, 2023.

(51) Int. Cl. G02B 27/01; H01Q 1/27; H05K 7/20

(52) U.S. Cl. CPC G02B 27/0172; H05K 7/20309; G02B 2027/0178; H01Q 1/273

(57) ABSTRACT

Examples include a wearable device such as smart glasses having a frame, a temple and onboard electronics components. The frame can define one or more optical element holders for holding respective optical elements within view of a user when the eyewear body is worn. The pair of temples can be connected to the eyewear frame for supporting the eyewear frame in position within view of the user when the eyewear body is worn. The antenna can be incorporated in at least a first of the pair of temples. The antenna can include an exciter circuit, at least a portion of a battery flex of the first of the pair of temples configured as an active element of the antenna and a metal component of the first of the pair of temples configured as a ground of the antenna.

### PRIORITY CLAIM

This application claims the benefit of U.S. Provisional Application No. 63/603,371, filed on Nov. 28, 2023, which is hereby incorporated by reference in its entirety.

### BACKGROUND

Trends in consumer electronics have consistently been towards greater miniaturization, while the functionalities of these devices demand increasingly ubiquitous and reliable wireless connectivity. Antenna systems forming part of such electronic devices (for example wearable devices such as smart glasses) often struggle to meet the conflicting requirements for compactness and for reliable transfer of large amounts of data (e.g., video content captured by a pair of smart glasses). These difficulties are exacerbated in wearable devices, where available space for antenna systems is often at a minimum. Adding to design challenges, modern wireless communication standards necessitate an antenna architecture with multiple antenna elements, each of which has to be electrically isolated from one another to ensure little to no correlation between the different antenna elements. These antenna elements should be capable of simultaneous operation with high radiation efficiency on wide and far apart frequency bands.

### BRIEF DESCRIPTION OF THE DRAWINGS

The appended drawings merely illustrate a selection of example embodiments of the present disclosure and cannot be considered as limiting its scope. To facilitate collation of numbered items in the description to the drawings, the first digit of each numbered item corresponds to the figure in which that item first appears. In the drawings:

FIG. 1 is a perspective view of an electronics enabled eyewear device having a frame and a pair of temples, according to an example embodiment.

FIG. 2 is a cross-section of one of the pair of temples of the eyewear device of FIG. 1, according to an exemplary embodiment.

FIG. 3 is a perspective view of portions of the eyewear device of FIGS. 1 and 2 with portions of the one of the pair of temples removed, according to an exemplary embodiment.

FIG. 4 is a schematic view of a heat transfer pathway that can be utilized within one or more of the pair of temples according to an exemplary embodiment.

FIG. 5 is a plan view of an exemplary configuration of components of the one of the pair of temples with portions of a housing of the temple removed, according to an exemplary embodiment.

FIG. 6 is a schematic view of an antenna formed by components of one of a pair of temples, according to an exemplary embodiment.

FIG. 7 is a schematic view of an electric field distribution in the first fundamental frequency of the antenna of either FIG. 5 or 6, according to an exemplary embodiment.

FIG. 8 is a radiation pattern of the antenna of either FIG. 5 or 6, according to an exemplary embodiment.

FIG. 9 is a schematic view of another antenna formed by components of one of the pair of temples, according to an exemplary embodiment.

FIG. 10 is a response of the antenna of FIG. 9 for a first fundamental frequency when a switch of FIG. 9 is open and a response of the antenna of FIG. 9 for a second frequency when the switch is closed, according to an exemplary embodiment.

FIG. 11 is a perspective view of an electronics-enabled eyewear device having an antenna system with at least three antennas, according to an example embodiment.

### DETAILED DESCRIPTION

The subject matter disclosed herein generally relates to eyewear, and more specifically to electronics-enabled eyewear with wireless communication enabled onboard electronic components facilitated by one or more antennas and a transceiver. At least one antenna can be carried by the temple as further discussed herein. Additionally, the eyewear can include an antenna system that includes multiple antennas. Such an antenna system can be carried by the temple(s), or a combination of the temple(s) and the frame of the eyewear, for example. One contemplated antenna can include a non-loop patch or stripe antenna having a hybrid structure that includes a slot and planar inverted-F antenna (PIFA) configuration as further discussed and illustrated herein. However, antenna systems are contemplated that can include loop antennas, non-loop antennas (e.g., monopole or dipole antennas) and/or a combination of various known antenna(s) in alternative to or in addition to the patch antennas specifically discussed herein. Various non-loop antenna structures (sometimes referred to as an electric type or E-type antenna) are also contemplated including a loaded monopole conductor (e.g., inverted F antenna, inverted L antenna, etc.), a dipole conductor, or the like. As used herein, the term non-loop conductor/antenna (sometimes called an incomplete loop antenna herein) refers to dipole conductors/antennas and/or monopole conductor/antennas, and excludes loop antenna/conductors. Further, the disclosed antenna elements provided by the respective loop and non-loop conductors are to be understood as providing actively driven antenna elements, which are to be distinguished from passive ground plane elements such as that which is in some cases provided by printed circuit board (PCB) ground planes elements or extensions thereof. According to one example, the antenna systems disclosed can include a common transceiver configured for wireless communication and the antennas are connected to the transceiver and configured to receive (and transmit) various signals.

The antenna system may further include electronics configured to provide frequency-domain discrimination. However, it is contemplated that the antenna(s) disclosed can be configured (e.g., sized, constructed and/or shaped) for two or more wireless communication (operation) modalities according to some examples. Thus, the antenna can be configured to receive and/or transmit data at approved frequency ranges for 3G, 4G, 5G, 6G, etc. communication (generally between 699 MHz to 2200 MHz range), and can be configured to cover even wider frequencies if desired. Specific cellular bands supported can include n12, n13, n5, n8, n1, n2, n3, n66, etc. The antennas can be configured to receive and/or transmit data at other approved frequency ranges for Global Positioning System (GPS), such as bands L1 to L5 (e.g., between 1.2 GHz range and 1.6 GHz range), BLUETOOTH® (e.g., 2.4 GHz) and/or Wi-Fi (e.g., 2.4, 5 or 6 GHz), for example. However, it is contemplated that the antennas can operate at any desired range of microwave frequencies (from 300 MHz to 30 GHz).

As used herein an active antenna element (or simply active element) is an actively driven antenna element that is a conductor for the antenna that radiates/receives EM signals. An antenna is a device used to transmit and/or receive radio waves. It converts electric currents into radio waves and vice versa. An antenna system is a plurality of antennas. An antenna provides the interface between radio waves propagating through space and electric currents moving in one or more metal conductors. In general, an antenna refers to the entire arrangement of metal conductors used for radiating or receiving radio waves. It can take on many different shapes and configurations. An antenna element (or active antenna element) is a basic building block of an antenna. It is a single radiating piece or section of an antenna. Antennas are often composed of multiple antenna elements working together to transmit/receive signals. An antenna element is a component(s) or part(s) of the overall antenna structure. The term “element” refers to one or more radiating pieces, whereas “antenna” refers more broadly to the overall system of components.

It will be understood that the antenna systems disclosed herein provide improved signal reception, improved radiation efficiency, improved polarization diversity, and other benefits when compared to existing antenna systems for handheld or wearable devices while being integrated effectively into a constricted space in existing electronically enabled eyewear design.

The present inventors recognize that the temple of electronically enabled eyewear, specifically around the ear, is typically void of complicated circuitry. This is because the area is typically in contact with the skin and heat generated by complicated circuitry in this area may not be tolerated by the wearer with comfort. Additionally, for antenna placement, this location within the temple was not considered very desirable due to its close proximity to the head. Indeed, classic electric type antennas such as inverted-F antennas, inverted-L antennas, dipole inverted-L antennas, etc. would struggle for radiation efficiency in the temple as the temple is shaped to be elongate (front to back) but is space constricted medial-laterally. Furthermore, the geometry of the temple would result in placing the active electric type antenna in such a location (e.g., in the middle of a relatively long but narrow/constricted element) that would result in RF currents traveling to the tip of the temple and front of the temple in relatively similar amounts, effectively canceling each other in an undesired manner. A traditional patch antenna was not considered appropriate for the temple as such antenna design requires a large ground plane(s) to provide effective space for fringe electric fields. However, the present inventors recognized antenna design(s) that utilize various components of the temple, including existing components within the temple and additional component(s) that can be used as shorting bars/tuning elements and/or ground plane(s) making the antenna designs disclosed effective as discussed and illustrated herein.

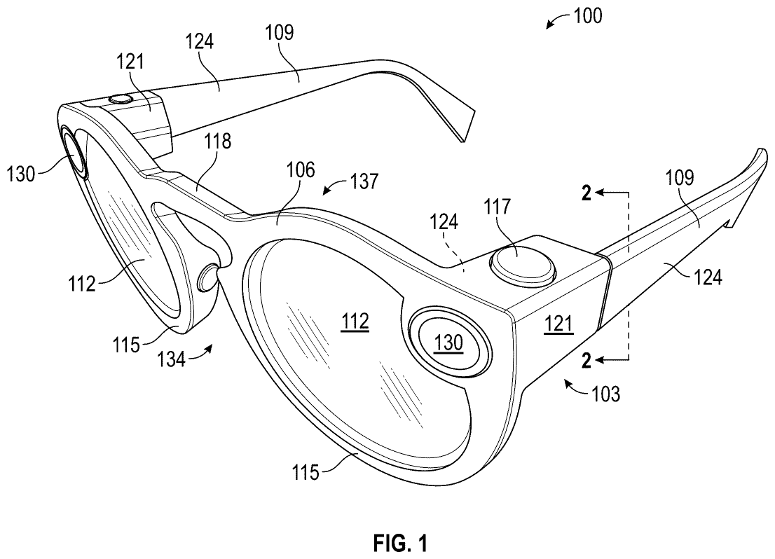

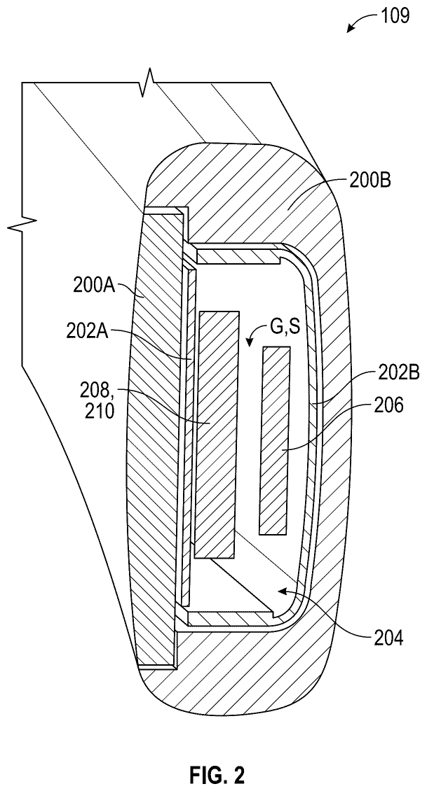

Various embodiments of an antenna system according to this disclosure will be described below with reference to an electronic device in the example form of an eyewear device that incorporates one or more of the disclosed antennas. Such eyewear device may include one or more cameras, indicator lights, memory, control circuitry, battery elements, and wireless communication circuitry among other components. An example embodiment of such an eyewear device in which different embodiments of the antennas can be incorporated will first be described with reference to FIG. 1, after which a series of different example embodiments of antennas incorporating the different respective embodiments will be described with reference to FIGS. 2-11.

FIG. 1 shows an oblique front view of an electronic device in the example form of an electronics enabled eyewear device 100, also referred to as a pair of smart glasses. The eyewear device 100 includes a body 103 comprising a front piece or frame 106 and a pair of temples 109 moveably connected to the frame 106 for supporting the frame 106 in position on a user's face when the eyewear device 100 is worn. The frame 106 can be made from any suitable material such as plastics, composite, or metal, including any suitable shape memory alloy.

The eyewear device 100 has a pair of optical elements in the example form of a pair of optical lenses 112 held by corresponding optical element holders or lens holders in the form of a pair of lens rims 115 forming part of the frame 106. According to one example, the optical lenses 112 can be constructed of a chemically-strengthened lithium aluminosilicate (LAS) glass. The rims 115 are connected by a bridge 118. In other embodiments, of one or both of the optical elements can be a display, a display assembly, or a lens and display combination. The eyewear device 100 can, in such embodiments, comprise a virtual reality display or a see through augmented reality display.

The frame 106 includes a pair of end pieces (or chunks) 121 defining lateral end portions of the frame 106. In this example, at least some electronics components are housed in one or both of the end pieces 121. In some embodiments, the frame 106 can be formed of a single piece of material, so as to have a unitary or monolithic construction.

The temples 109 are coupled to the respective end pieces 121. In this example, the temples 109 are coupled to the frame 106 by respective hinges (articulating joint) so as to be hingedly movable between a wearable mode (as shown in FIG. 1) and a collapsed mode in which the temples 109 are pivoted towards the frame 106 to lie substantially flat against it. In other embodiments, the temples 109 can be coupled to the frame 106 by any suitable means. Each of the temples 109 includes a front portion that is coupled to the frame 106 and a suitable rear portion for coupling to the ear of the user, such as the curved earpiece illustrated in the example embodiment of FIG. 1. The temples 109 can be made from any suitable material(s) such as plastics, composite, and/or metal.

In this description, directional terms such as front, back, forwards, rearwards, outwards and inwards are to be understood with reference to a direction of view of a user when the eyewear device 100 is worn. Thus, the frame 106 has an outwardly directed front side 134 facing away from the user when worn, and an opposite inwardly directed rear side 137 side facing towards the user when the eyewear device 100 is worn. Similarly, the terms horizontal and vertical as used in this description with reference to different features of the eyewear device 100 are to be understood as corresponding to the orientation of the eyewear device 100 when it is level on the face of a user looking forwards. A horizontal or lateral direction of the eyewear device 100 thus extends more or less between the end pieces 121, while a vertical or upright direction of the eyewear device 100 extends transversely to the horizontal direction, such that the lenses 112 can be said to have a more or less vertical or upright orientation.

The eyewear device 100 has onboard electronic components 124 (sometimes called just electronics or components herein) including any one or combination of an antenna(s) (discussed further subsequently), a camera, a microphone, a speaker, a battery, a display device, a computing device, such as a computer, which can, in different embodiments, be of any suitable type so as to be carried by the eyewear body 103. In some embodiments, various components comprising the onboard electronics 124 are at least partially housed in one or both of the temples 109. Additionally, various components of the onboard electronics 124 are housed in the lateral end pieces 121 of the frame 106. As discussed above, the onboard electronics 124 includes one or more processors with memory, wireless communication circuitry, and a power source (this example embodiment being a rechargeable battery, e.g. a lithium-ion battery or solid state battery). The onboard electronics 124 comprises low-power, high-speed circuitry, and, in some embodiments, a display processor. Various embodiments may include these elements in different configurations or integrated together in different ways. As further discussed, the antenna systems described herein may be housed in one or both of the temples 109 and additionally in the frame 106. Thus, for example, certain electronics components such as the transceiver may in some embodiments be housed in the temple 109 as further discussed and illustrated subsequently.

As mentioned, the onboard electronics 124 includes a rechargeable battery. In some embodiments, the battery is disposed in one of the temples 109 such as near or at a tip of one of the temples 109 and is electrically coupled to the remainder of the onboard electronics 124.

The eyewear device 100 is camera-enabled, in this example comprising a camera 130 mounted in one of the end pieces 121 and facing forwards so as to be aligned more or less with the direction of view of a wearer of the eyewear device 100. The camera 130 is configured to capture digital still as well as digital video content. Operation of the camera 130 is controlled by a camera controller provided by the onboard electronics 124, image data representative of images or video captured by the camera 130 being temporarily stored on a memory forming part of the onboard electronics 124. In some embodiments, the eyewear device 100 can have a pair of cameras 130, e.g. housed by the respective end pieces 121.

The eyewear device 100 further includes one or more input and output devices permitting communication with and control of the camera 130. In particular, the eyewear device 100 includes one or more input mechanisms for enabling user control of one or more functions of the eyewear device 100. In this embodiment, the input mechanism comprises a button 117 mounted on the frame 106 so as to be accessible on top of one of the end pieces 121 for pressing by the user.

The eyewear device 100 is, in this example embodiment, configured for wireless communication with external electronic components or devices, to which end the onboard electronics 124 is connected to one or more antennas integrated in the body 103 of the eyewear device 100.

Eyewear device 100 including optical lenses 112 can have a construction as described variously in U.S. Patent Numbers United States Patent Nos. U.S. Pat. No. 9,726,904, titled EYEWEAR WITH CONDUCTIVE TEMPLE JOINT (filing date, Sep. 29, 2015); U.S. Pat. No. 9,482,882 titled EYEWEAR HAVING SELECTIVELY EXPOSABLE FEATURE (filed Apr. 15, 2015); and U.S. Pat. No. 9,482,883 titled EYEWEAR HAVING LINKAGE ASSEMBLY BETWEEN A TEMPLE AND A FRAME filed (Apr. 15, 2015), U.S. Pat. No.10,877,293, titled EYEWEAR DEVICE LENS RETENTION MECHANISM, (filed Jan. 18, 2018), U.S. Pat. No. 11,063,338, titled HYBRID ANTENNA SYSTEM FOR WEARABLE DEVICES, (filed Jan. 24, 2019), U.S. Pat. No. 10,534,203, titled NEAR-FIELD ANTENNA FOR EYEWEAR, (filed Jul. 31, 2017), the contents of all of which are incorporated herein in their entirety.

FIG. 2 shows a cross-sectional view of one of the temples 109 of the eyewear device 100 of FIG. 1. The temple 109 includes one or more covers 200A and 200B, temple supports 202A and 202B, a cavity 204, a battery flex 206 and a heat transfer device 208.

The one or more covers 200A and 200B can be a plastic or other rigid material such as cellulosic plastic (e.g., cellulosic acetate), an eco-plastic material, a thermoplastic material, or the like. The one or more covers 200A and 200B can be an overmold that encloses, embeds or otherwise encases the temple supports 202A and 202B. Put another way, the one or more covers 200A and 200B can form an outer cap for the temple 109 and can extend longitudinally along a length of the temple 109 from the articulated joint toward a second longitudinal end (tip) of the temple 109. The temple supports 202A and 202B can be another material that extends longitudinally within the one or more covers 200A and 200B. Together the temples supports 202A and 202B can form the cavity 204. The cavity 204 can be configured to carry some of the onboard electronics 124 (FIG. 1) as further discussed and illustrated herein including, for example, the one or more processors with memory, wireless communication circuitry, and a power source (battery).

The temple supports 202A and 202B can be configured as a core wire equivalent, frame, stiffener or other structural component to provide structural integrity to the eyewear body 103 (i.e. the temple(s) 109 and/or the frame 106). The temple supports 202A and 202B can be constructed of a relatively flexible conductive metal or metal alloy material such as one or more of an aluminum, an alloy of aluminum, alloys of nickel-silver, and a stainless steel according to some embodiments.

Optionally, the cavity 204 can additionally carry the battery flex 206 and the heat transfer device 208, and a battery (not shown) therein. The battery flex 206 can extend longitudinally along a portion of the longitudinal length of the temple 109 and can engage the battery (not shown) at or adjacent the second longitudinal end. The battery flex 206 can be relatively thin in a medial-lateral direction and can be constructed of a relatively flexible conductive metal or metal alloy material such as one or more of an aluminum, an alloy of aluminum, copper, gold, alloys of nickel-silver, and a stainless steel according to some embodiment. Thus, the battery flex 206 can be a flexible electrically conductive component that extends longitudinally along at least a portion of a longitudinal length of the first of the pair of temples and couples to the battery (not shown) for structural support thereof.

The heat transfer device 208 can extend generally parallel with the battery flex 206 in an interfacing relationship therewith. The heat transfer device 208 can be positioned adjacent the battery flex 206 but can be spaced therefrom by a gap G. This gap G can form a slot S (an opening) between the heat transfer device 208 and the battery flex 206. Some of the onboard electronic components 124 (FIG. 1) such as the one or more processors can comprise a heat source that generates heat during electrically powered operation. The heat transfer device 208 can act as a heat transfer pathway to transfer the heat generated by the onboard electronic components 124 (FIG. 1) away therefrom so as to reduce the likelihood of localized heating adjacent the onboard electronic components 124 (FIG. 1). As such, the heat transfer device 208 is thermally coupled to the heat source to provide a heat sink for the heat source and can be coupled to another heat sink (e.g., the battery or another component) at a second portion thereof.

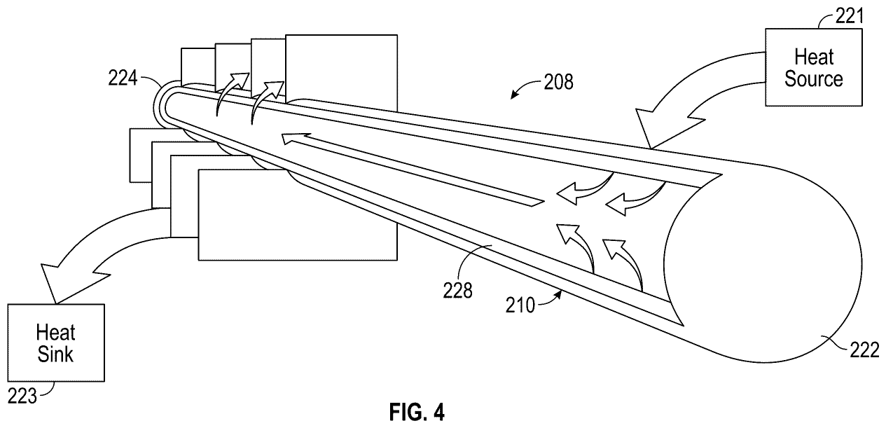

The heat transfer device 208 can be a core wire (constructed of a heat conductive material) or can be a vapor chamber 210 such as a heat pipe as further discussed herein in reference to FIG. 4. According to some examples, the heat transfer device 208 (e.g., the vapor chamber 210) can function as the temple support such that a dedicated temple support 202A and/or 202B is not necessary in all embodiments.

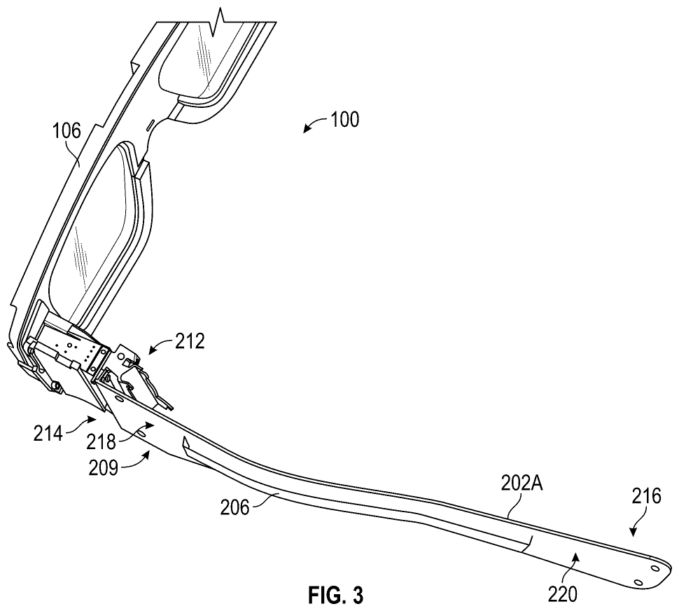

FIG. 3 shows part of the eyewear device 100 including part of the frame 106 and one of the temples 109. The one or more covers 200A and 200B of FIG. 2 are removed in FIG. 3 as is the temple support 202B. The heat transfer device 208 (FIG. 2) is also not illustrated in FIG. 3. FIG. 3 illustrates the temple support 202A extending from a hinge 212 (an articulating joint) at a first longitudinal end 214 of the temple 109 to a second longitudinal end 216. The battery flex 206 can be positioned between the first longitudinal end 214 and the second longitudinal end 216 and can be in a spaced relationship from the temple support 202A. The battery flex 206 can extend generally parallel with the temple support 202A. The battery flex 206 at a first longitudinal end thereof can abut a printed circuit board (PCB) and communication device (e.g., a transceiver), for example. These onboard electronics are not specifically illustrated in FIG. 3 but are located at area 218 as indicated in FIG. 3. The battery flex 206 at a second longitudinal end thereof can abut the battery (not shown in FIG. 3) located at area 220. The temple support 202A can include features such as apertures for receiving fasteners that mechanically couple the aforementioned electronics thereto.

FIG. 4 illustrates a schematic view of the heat transfer device 208 comprising a vapor chamber 210 according to one example. The vapor chamber 210 (e.g., a heat pipe) can extend longitudinally within the temple 109 (FIG. 2) as previously discussed. The vapor chamber 210 can be thermally coupled to a heat source 221 (e.g., the PCB and the communication device) at a first portion 222 thereof and can be thermally coupled to a heat sink 223 (e.g., the battery and/or a thermal interface material (TIMs)) at a second portion 224 thereof. As shown in FIG. 4, the vapor chamber 226 can have a metal outer housing and a hollow central cavity surrounded by an outer housing. The hollow cavity can contain a working fluid (e.g., deionized water). The working fluid can be evaporated to a vapor at the first portion 222 adjacent the heat source 104. The vapor can travel the length of the vapor chamber 226 as illustrated to the second portion 224. At the second portion 224 adjacent the heat sink 223 the vapor can condense back to fluid and the heat is released to the heat sink 223. The fluid can be absorbed back into a wick 228 that extends substantially the length of the vapor chamber 210. The working fluid can travel the length of the wick 228 back from the second portion 224 to the first portion 222 to repeat the cycle described above.

According to the embodiment of FIG. 4, the vapor chamber 210 has the wick 228 that extends along at least a portion of a lateral length thereof. The vapor chamber 210 can be configured to carry the working fluid that is evaporated to a vapor at a first end portion (first portion 222) thereof by the heat from the heat source 221. The vapor chamber 210 can direct the vapor to a second end portion (second portion 224) thereof where the vapor condenses back to the working fluid and is absorbed by the wick 228. As discussed with regard to FIG. 2, according to some examples the vapor chamber 210 can function as the temple support such that the temple support 202A and/or 202B (FIG. 2) is not necessary according to some embodiments.

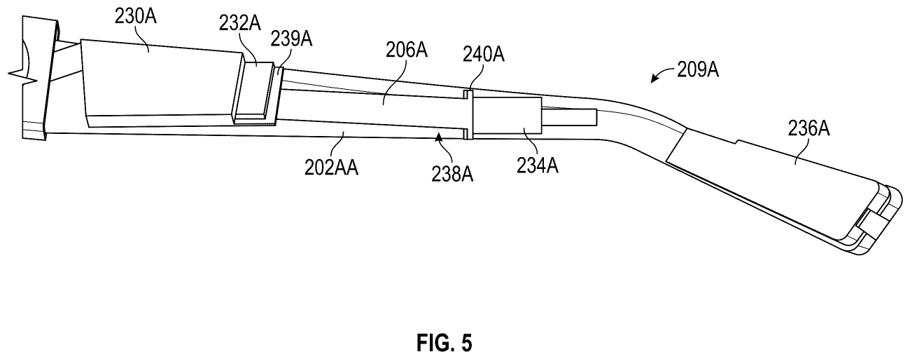

FIG. 5 shows an example of a temple 209A according to another example embodiment. The temple 209A can be constructed in a manner similar to the temple 109 discussed previously in regards to FIGS. 1-4. Portions of the cover of the temple 209A have been removed to show various components including onboard electronics such as the PCB 230A and a communication device 232A. FIG. 5 additionally illustrates a temple support 202AA, battery flex 206A, a speaker 234A and a battery 236A. The temple 209A can additionally include an antenna 238A therein. The antenna 238A can include the temple support 202AA or heat transfer device (not shown), the battery flex 206A, a first shorting bar 239A and a second shorting bar 240A.

As an example, the antenna 238A can be a driven antenna with the battery flex 206A acting as an active antenna element that is electrically connected to the communication device 232A (e.g., a transceiver system) incorporated in the PCB 230A. The battery flex 206A can be constructed of a metal, metal alloy or other suitable electrically conductive material so as to be operable as the active antenna element. The PCB 230A can be electrically connected to the active antenna element (the battery flex 206A) at a signal feed (not shown) at or adjacent the first shorting bar 239A. Additionally, the temple support 202AA or heat transfer device (not shown) via connection with the first shorting bar 239A and/or the second shorting bar 240A can act as the primary ground plane for antenna 238A. According to some embodiments, the PCB 230A, the communication device 232A, the speaker 234A and/or the battery 236A, which can include conductive metal components, and can be electrical connections to the ground plane or can act as the ground plane.

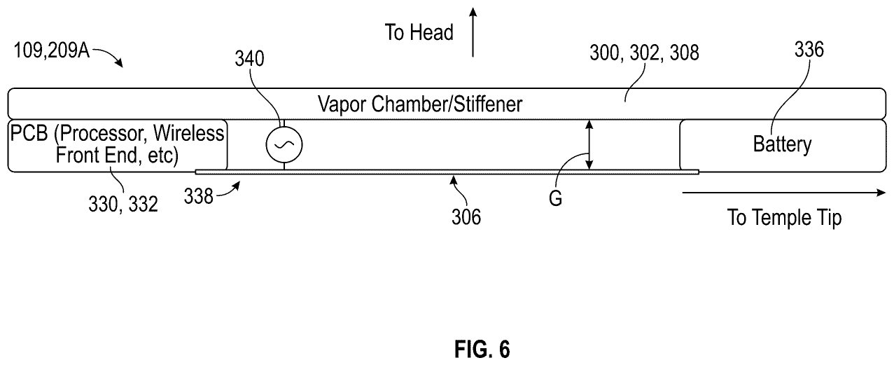

FIG. 6 shows a schematic example of an antenna 338 that can be carried by the temple 109, 209A, etc. of the eyewear device. The antenna 338 can include a PCB 330 (which can include a communication device 332), a ground 300 (e.g., a temple support 302 or a heat transfer device 308), a battery flex 306, a battery 336 and a feed point 340 (e.g., an exciter circuit). As with the prior embodiment of FIG. 5, the battery flex 306 can be the active antenna element. The battery flex 306 can extend longitudinally between and can be connected to the PCB 330 and the battery 336. The PCB 330 and the battery 336 can provide for electrical connection (shorting bar(s)) to the primary ground 300 (e.g., the temple support 302 or a heat transfer device 308). The construction of the heat transfer device 308 can be that of the heat transfer device 208 discussed previously (e.g., can be a vapor chamber according to one embodiment). As previously discussed, the battery flex 306 can be spaced from the ground 300 by a gap G. This gap G can form a slot (an opening) between the ground 300 (e.g., the heat transfer device 308 or the temple support 302) and the battery flex 306. This gap G can be between 1.5 mm and 5 mm, for example. Conversely, the design of FIG. 6 could be modified according to further embodiments such that the battery flex 306 can act as the ground 300 and the active antenna element can be the heat transfer device 308 or the temple support 302. However, the ground should be dimensionally wider than the active antenna element. Additionally, it is preferred (but not required) to have the active antenna element be further away from the head of the user when worn, while keeping the ground closer to the head.

Thus, the antennas of FIGS. 5 and 6 are incorporated in at least a first of the pair of temples 109, 209A. The antenna 238A, 338 can include an exciter circuit (the feed point). At least a portion of the battery flex 206A, 306 of the first of the pair of temples can be configured as an active element of the antenna 238A, 338 and a metal component (e.g., the temple support 202AA, 302 and/or the heat transfer device 308) of the first of the pair of temples can be configured as a primary ground of the antenna 338A, 338. The battery flex 206A, 306 can be spaced by the gap G from the metal component (e.g., the temple support 202AA, 302 and/or the heat transfer device 308) along at least a majority of a longitudinal length thereof. The metal component (e.g., the temple support 202AA, 302 and/or the heat transfer device 308) is substantially continuous and extends substantially in parallel with the battery flex 206A, 306A.

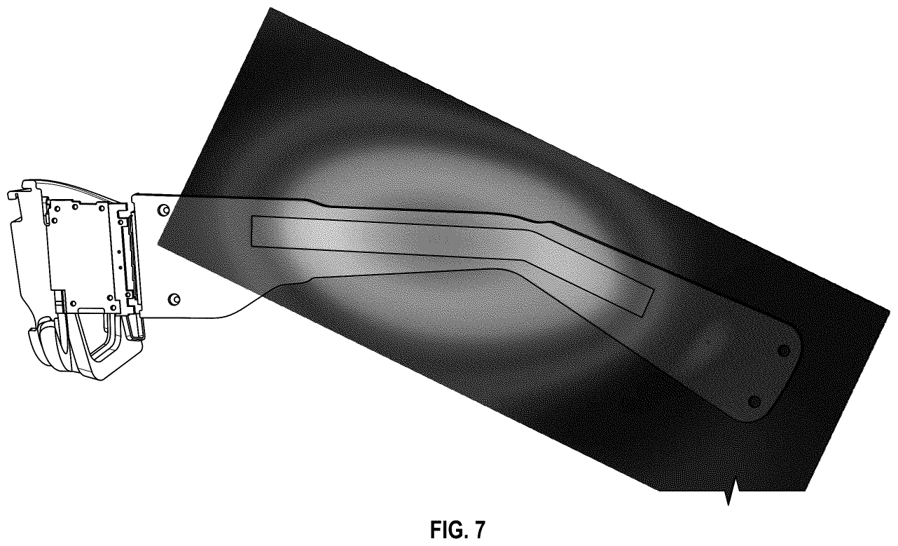

FIG. 7 shows a schematic view of an electric field distribution in the first fundamental frequency of the antenna of either FIG. 5 or 6. The electric field distribution is very strong in the middle of the antenna but weakens as one travels toward the longitudinal ends (e.g., closer to the PCB and the battery).

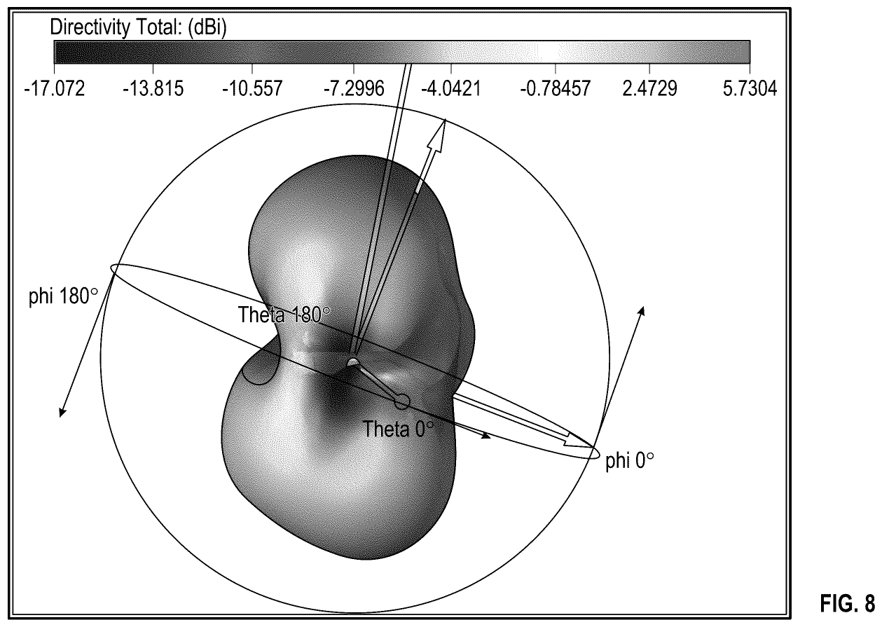

FIG. 8 shows a radiation pattern of the antenna of either FIG. 5 or 6. The radiation pattern has nulls that point toward the head, which demonstrates good efficiency performance for the antenna when worn and is also excellent from a regulatory compliance perspective since energy is not moving towards the head. Peak radiation (indicated with arrow) is in a direction away from the head of the user.

The examples of FIGS. 5-8 demonstrate that components of the temple can be utilized in forming/integrating an antenna using some existing components of the temple such as the battery flex, the heat transfer device (e.g., the vapor chamber), the temple support, thereby reducing component count and design complexity that would otherwise be needed to provide for a dedicated antenna within the temple.

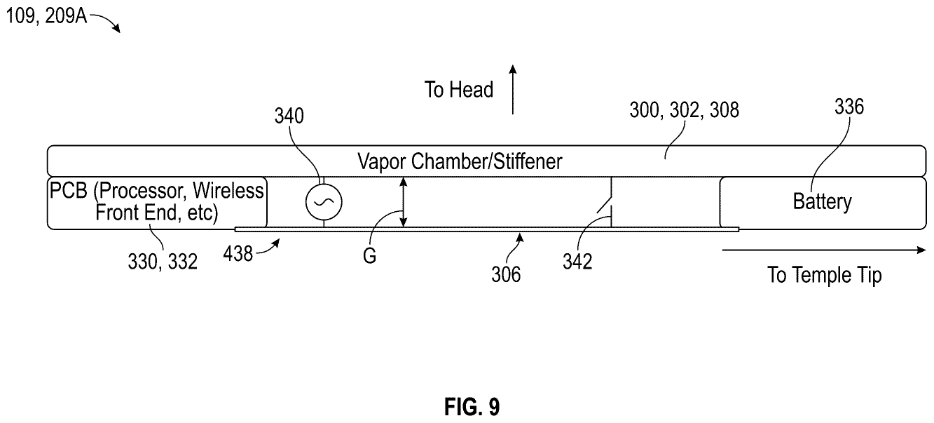

FIG. 9 shows a schematic example of an antenna 438 that can be carried by the temple 109, 209A of the eyewear device. The antenna 438 can include the PCB 330 (which can include the communication device 332), the primary ground 300 (e.g., the temple support 302 or the heat transfer device 308), the battery flex 306, the battery 336 and the feed point 340 (e.g., the exciter circuit) as previously discussed. Additionally, the antenna 438 can include at least one switch 342 positioned in the gap G between the battery flex 306 and the metal component (the temple support 302 or the heat transfer device 308). The at least one switch 342 can be configured as a selectively operable shorting element that selectively electrically connects the active antenna element (the battery flex 306) to the ground 300.

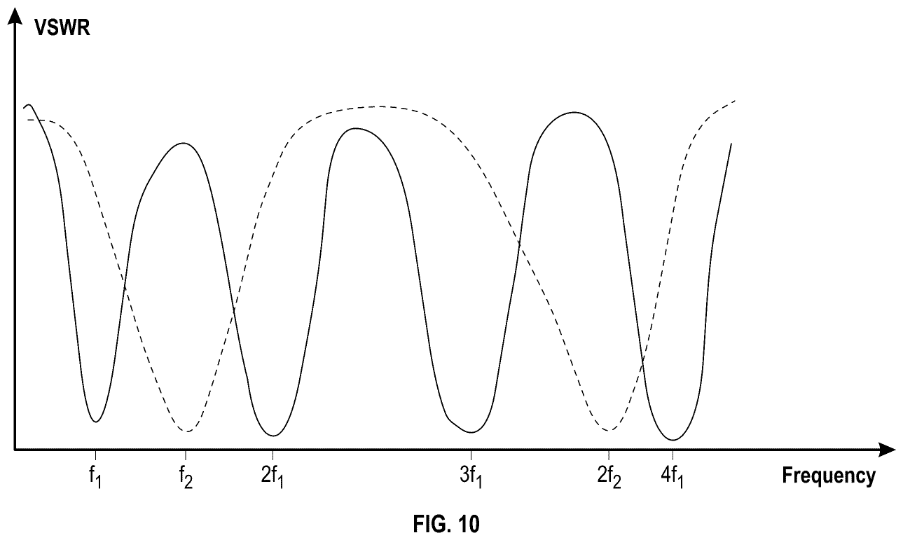

FIG. 10 graphically shows how a fundamental frequency of the antenna 438 (FIG. 9) is altered by the at least one switch 342 being selectively opened and closed. More particularly, FIG. 10 graphs the response of the antenna 438 of FIG. 9 for a first fundamental frequency f₁ when the switch 342 of FIG. 9 is open and a response of the antenna 438 of FIG. 9 for a second fundamental frequency f₂ when the switch 342 is closed. The fundamental frequencies can be tuned as desired by changing the length of the opening (the gap G of FIG. 9 and further the length of the battery flex 306-—the active antenna element between shorting elements such as (but not limited to) the PCB 330 and the battery 336 as the edges of the radiation area) and the location of the at least one switch 342 (FIG. 9) along the battery flex 306, for example. The concept of FIGS. 9 and 10 controls the antenna 438 in a time-duplexed manner (e.g., the switch 342 can be selectively controlled to open and close in a time based manner as desired). Although only one switch 342 is shown in FIG. 9, it is contemplated that two or more switches could be utilized according to some examples. It is further recognized that for a second temple (e.g., refer to the second temple 109 in FIG. 1), another antenna can be configured to operate at different fundamental frequency(s) so as to allow for operation of multiple temple carried antennas at various desired wireless bands.

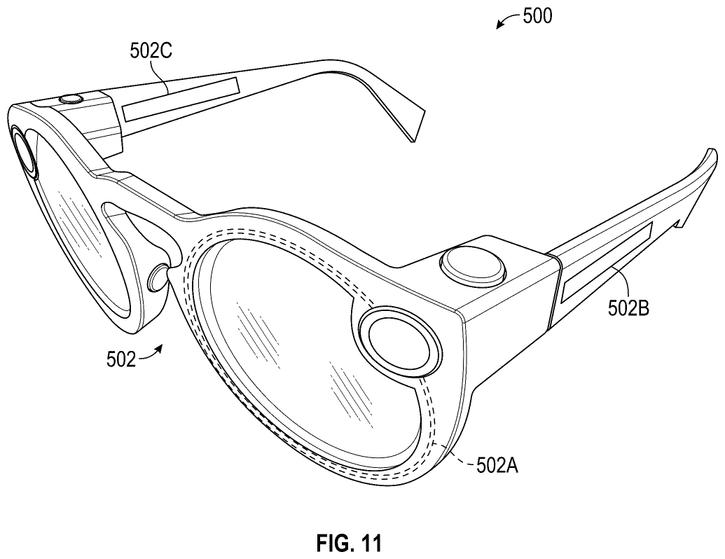

FIG. 11 illustrates the concept of having multiple antennas including those configured for operation at different frequency bands carried by an eyewear device 500. FIG. 11 shows is a highly schematic view of eyewear device 500 having a similar construction to that of the eyewear 100 of FIG. 1 discussed previously. The eyewear device 500 includes the frame, at least one of the temples and the one or more onboard electronics components as previously discussed. The eyewear 500 additionally includes an antenna system 502 including a first antenna 502A, a second antenna 502B and a third antenna 502C. Although not specifically numbered, the eyewear device 500 can include a PCB, a communication device (e.g., a transceiver, a hinges and some of the onboard electrical components).

The first antenna 502A can be configured as a loop conductor. This loop conductor has a construction that is discussed in prior filed patent applications by the applicant including US Patent Application Publication Nos. 2019/0229395 and 2019/0033622, the entire contents of each of which is incorporated herein by reference in its entirety. According to one example, the loop conductor is provided by the lens rim of the frame or by the lens itself. The lens rim can be constructed of a metal, metal alloy or other suitable electrically conductive material so as to be operable as the first antenna 502A.

The second antenna 502B and the third antenna 502C, which are carried by the respective temples 109, can have a different construction from the first antenna 502A. Thus, while the first antenna 502A can be constructed as a loop antenna, the second antenna 502B and the third antenna 502C can be a non-loop antenna (sometimes called an incomplete loop, dipole, or monopole antenna) and/or can have the hybrid gap and patch construction discussed previously with regard to the antennas of FIGS. 5-10. The second antenna 502B and the third antenna 502C (and indeed the first antenna 502A) can have very low levels of correlation between themselves. Thus, the antennas essentially operate independent of one another. Thus, for example, the second antenna 502B can be configured to support at least GPS bands L1 and L5, while the third antenna 502C can be configured to support at least Bluetooth band and Wi-Fi band, for example. However, the present application contemplates that the first antenna 502A, second antenna 502B, third antenna 502C or any of the other antennas discussed herein can be configured as desired to communicate at any desired range of microwave frequencies (from 300 MHz to 30 GHz).

As used herein, the term “memory” refers to a machine-readable medium able to store data temporarily or permanently and may be taken to include, but not be limited to, random-access memory (RAM), read-only memory (ROM), buffer memory, flash memory, and cache memory. While the machine-readable medium is shown, in an example embodiment, to be a single medium, the term “machine-readable medium” should be taken to include a single medium or multiple media (e.g., a centralized or distributed database, or associated caches and servers) able to store the instructions. The term “machine-readable medium” shall also be taken to include any medium, or combination of multiple media, that is capable of storing instructions (e.g., instructions) for execution by a machine, such that the instructions, when executed by one or more processors of the machine, cause the machine to perform any one or more of the methodologies described herein. Accordingly, a “machine-readable medium” refers to a single storage apparatus or device, as well as “cloud-based” storage systems or storage networks that include multiple storage apparatus or devices. The term “machine-readable medium” shall accordingly be taken to include, but not be limited to, one or more data repositories in the form of a solid-state memory (e.g., flash memory), an optical medium, a magnetic medium, other non-volatile memory (e.g., erasable programmable read-only memory (EPROM)), or any suitable combination thereof. The term “machine-readable medium” specifically excludes non-statutory signals per se.

In some further example embodiments, the machines discussed herein can include I/O components such as biometric components, motion components, camera, environmental components, or position components, among a wide array of other components. For example, the biometric components include components to detect expressions (e.g., hand expressions, facial expressions, vocal expressions, body gestures, or eye tracking), measure biosignals (e.g., blood pressure, heart rate, body temperature, perspiration, or brain waves), identify a person (e.g., voice identification, retinal identification, facial identification, fingerprint identification, or electroencephalogram based identification), and the like. The motion components include acceleration sensor components (e.g., accelerometer), gravitation sensor components, rotation sensor components (e.g., gyroscope), and so forth. The environmental components include, for example, illumination sensor components (e.g., photometer), temperature sensor components (e.g., one or more thermometers that detect ambient temperature), humidity sensor components, pressure sensor components (e.g., barometer), acoustic sensor components (e.g., one or more microphones that detect background noise), proximity sensor components (e.g., infrared sensors that detect nearby objects), gas sensor components (e.g., machine olfaction detection sensors, gas detection sensors to detect concentrations of hazardous gases for safety or to measure pollutants in the atmosphere), or other components that may provide indications, measurements, or signals corresponding to a surrounding physical environment. Camera components include any information for image capture, such as saturation control, pixel processing, sound capture, three dimensional image processing, etc. The position components include location sensor components (e.g., a Global Positioning System (GPS) receiver component), altitude sensor components (e.g., altimeters or barometers that detect air pressure from which altitude may be derived), orientation sensor components (e.g., magnetometers), and the like.

Communication can be implemented using a wide variety of technologies. The I/O components may include communication components operable to couple the machine to a network or devices via a coupling. For example, the communication components include a network interface component or another suitable device to interface with the network. In further examples, communication components include wired communication components, wireless communication components, cellular communication components, near-field communication (NFC) components, BLUETOOTH® components (e.g., BLUETOOTH® Low Energy), WI-FI® components, and other communication components to provide communication via other modalities. The devices may be another machine or any of a wide variety of peripheral devices (e.g., a peripheral device coupled via a Universal Serial Bus (USB)).

Moreover, in some embodiments, the communication components detect identifiers or include components operable to detect identifiers. For example, the communication components include radio frequency identification (RFID) tag reader components, NFC smart tag detection components, optical reader components (e.g., an optical sensor to detect a one-dimensional bar codes such as a Universal Product Code (UPC) bar code, multi-dimensional bar codes such as a Quick Response (QR) code, Aztec Code, Data Matrix, Dataglyph, MaxiCode, PDF417, Ultra Code, Uniform Commercial Code Reduced Space Symbology (UCC RSS)-2D bar codes, and other optical codes), acoustic detection components (e.g., microphones to identify tagged audio signals), or any suitable combination thereof. In addition, a variety of information can be derived via the communication components, such as location via Internet Protocol (IP) geo-location, location via WI-FI® signal triangulation, location via detecting a BLUETOOTH® or NFC beacon signal that may indicate a particular location, and so forth.

In various example embodiments, one or more portions of the network can be an ad hoc network, an intranet, an extranet, a virtual private network (VPN), a local area network (LAN), a wireless LAN (WLAN), a wide area network (WAN), a wireless WAN (WWAN), a metropolitan area network (MAN), the Internet, a portion of the Internet, a portion of the public switched telephone network (PSTN), a plain old telephone service (POTS) network, a cellular telephone network, a wireless network, a WI-FI® network, another type of network, or a combination of two or more such networks. For example, the network or a portion of the network may include a wireless or cellular network, and the coupling may be a Code Division Multiple Access (CDMA) connection, a Global System for Mobile communications (GSM) connection, or another type of cellular or wireless coupling. In this example, the coupling can implement any of a variety of types of data transfer technology, such as Single Carrier Radio Transmission Technology (1xRTT), Evolution-Data Optimized (EVDO) technology, General Packet Radio Service (GPRS) technology, Enhanced Data rates for GSM Evolution (EDGE) technology, third Generation Partnership Project (3GPP) including 3G, fourth generation wireless (4G) networks, Universal Mobile Telecommunications System (UMTS), High Speed Packet Access (HSPA), Worldwide Interoperability for Microwave Access (WiMAX), Long Term Evolution (LTE) standard, others defined by various standard-setting organizations, other long range protocols, or other data transfer technology.

In example embodiments, the instructions are transmitted or received over the network using a transmission medium via a network interface device (e.g., a network interface component included in the communication components) and utilizing any one of a number of well-known transfer protocols (e.g., Hypertext Transfer Protocol (HTTP)). Similarly, in other example embodiments, the instructions are transmitted or received using a transmission medium via the coupling (e.g., a peer-to-peer coupling) to the devices. The term “transmission medium” shall be taken to include any intangible medium that is capable of storing, encoding, or carrying the instructions for execution by the machine, and includes digital or analog communications signals or other intangible media to facilitate communication of such software.

Furthermore, the machine-readable medium is non-transitory (in other words, not having any transitory signals) in that it does not embody a propagating signal. However, labeling the machine-readable medium “non-transitory” should not be construed to mean that the medium is incapable of movement; the medium should be considered as being transportable from one physical location to another. Additionally, since the machine-readable medium is tangible, the medium may be considered to be a machine-readable device.

Note that although the disclosure herein of a device that incorporates antenna systems, as disclosed, is directed primarily to the example embodiment of an eyewear device, antenna systems as disclosed may in other embodiments be incorporated in different types of electronic devices. Thus, for example, the disclosed antenna systems can be profitably employed in other wearable electronic devices, mobile electronic devices (such as mobile phones, tablets, or the like), and/or larger products such as motor vehicles or the like.

The foregoing description includes devices, systems techniques, instruction sequences, and computing machine program products that embody illustrative embodiments of the disclosure. In the above description, for the purposes of explanation, numerous specific details are set forth in order to provide an understanding of various embodiments of the disclosed subject matter. It will be evident, however, to those skilled in the art, that embodiments of the disclosed subject matter may be practiced without these specific details. In general, well-known instruction instances, protocols, structures, and techniques are not necessarily shown in detail.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The following numbered examples is a non-exhaustive list of selected illustrative embodiments in accordance with various aspects of the present disclosure.

### CLAIMS RELATED EXAMPLES

In some aspects, the techniques described herein relate to a wearable device including: an eyewear body including: an eyewear frame defining one or more optical element holders for holding respective optical elements within view of a user when the eyewear body is worn; and a pair of temples connected to the eyewear frame for supporting the eyewear frame in position within view of the user when the eyewear body is worn; an antenna incorporated in at least a first of the pair of temples, the antenna including an exciter circuit, at least a portion of a battery flex of the first of the pair of temples configured as an active element of the antenna and a metal component of the first of the pair of temples configured as a ground of the antenna.

In some aspects, the techniques described herein relate to a wearable device, wherein the antenna includes at least one switch extending across a gap between the battery flex and the metal component, wherein the at least one switch is configured as a shorting element that selectively electrically connects the active element to the ground.

In some aspects, the techniques described herein relate to a wearable device, wherein a fundamental frequency of the antenna is altered by the at least one switch being selectively opened or closed.

In some aspects, the techniques described herein relate to a wearable device, wherein the at least one switch allows the antenna to be controlled to selectively operate at a first frequency range or a second frequency range.

In some aspects, the techniques described herein relate to a wearable device, wherein the metal component is at least one of a temple support, a heat transfer device or a battery.

In some aspects, the techniques described herein relate to a wearable device, wherein the heat transfer device is a vapor chamber, and wherein the temple support or the vapor chamber is configured as a primary ground for the antenna.

In some aspects, the techniques described herein relate to a wearable device, wherein the antenna is positioned between electronics carried by the first of the pair of temples, wherein the electronics include a battery and a printed circuit board (PCB) that carries on-board communication electronics coupled to the antenna to communicate wireless signals via the antenna.

In some aspects, the techniques described herein relate to a wearable device, wherein the PCB has or is coupled to a shorting bar coupled to the battery flex.

In some aspects, the techniques described herein relate to a wearable device, wherein the metal component includes a vapor chamber that extends longitudinally from the PCB at a front portion of the first of the pair of temples to the battery at a rear portion of the first of the pair of temples.

In some aspects, the techniques described herein relate to a wearable device, wherein the antenna of the first of the pair of temples is configured to operate at two or more frequency ranges, and further including a second antenna carried by a second of the pair of temples, wherein the second antenna is configured to operate at two or more frequency ranges, wherein the two or more frequency ranges of the antenna differs from the two or more frequency ranges of the second antenna.

In some aspects, the techniques described herein relate to a wearable device, wherein the antenna is configured to support at least GPS bands L1 and L5, and wherein the second antenna is configured to support at least Bluetooth band and Wi-Fi band.

In some aspects, the techniques described herein relate to a wearable device, wherein the metal component is positioned between a head of the user when the eyewear body is worn and the battery flex.

In some aspects, the techniques described herein relate to a wearable device, wherein the battery flex is spaced by a gap from the metal component along at least a majority of a longitudinal length thereof.

In some aspects, the techniques described herein relate to a wearable device, where in the metal component is substantially continuous and extends substantially in parallel with the battery flex.

In some aspects, the techniques described herein relate to a method of operating an antenna in a wearable device, the method including: providing an eyewear frame defining one or more optical element holders for holding respective optical elements within view of a user and a pair of temples coupled to the eyewear frame; providing a metal component carried by a first of the pair of temples, wherein the metal component acts as a ground of the antenna; providing a battery flex carried by the first of the pair of temples with the battery flex spaced by a gap from the metal component for a least a majority of a longitudinal length thereof, wherein the battery flex acts as an active element of the antenna; and operating the antenna with the gap as a radiating aperture of the antenna.

In some aspects, the techniques described herein relate to a method, further including providing at least one switch extending across the gap between the battery flex and the metal component, wherein the at least one switch is configured as a shorting element that selectively electrically connects the active element to the ground.

In some aspects, the techniques described herein relate to a method, further including altering a fundamental frequency of the antenna by selectively opening and closing the at least one switch.

In some aspects, the techniques described herein relate to a method, further including operating the antenna at two or more frequency ranges.

In some aspects, the techniques described herein relate to a method, further including providing a second antenna carried by a second of the pair of temples, wherein the second antenna is configured to operate at two or more frequency ranges, wherein the two or more frequency ranges of the antenna differs from the two or more frequency ranges of the second antenna.

In some aspects, the techniques described herein relate to a method, further including operating the antenna at GPS band L1 or L5 and operating the second antenna at Bluetooth band or Wi-Fi band.

In some aspects, the techniques described herein relate to an wearable device including: an eyewear body including: an eyewear frame defining one or more optical element holders for holding respective optical elements within view of a user when the eyewear body is worn; a pair of temples connected to the eyewear frame for supporting the eyewear frame in position within view of the user when the eyewear body is worn; an antenna, including: an exciter circuit, at least a portion of a battery flex that is incorporated in a first of the pair of temples and that is configured as an active element of the antenna, and a metal component of the first of the pair of temples configured as a ground of the antenna.

In some aspects, the techniques described herein relate to an wearable device including: an eyewear body including: an eyewear frame defining one or more optical element holders for holding respective optical elements within view of a user when the eyewear body is worn; a pair of temples connected to the eyewear frame for supporting the eyewear frame in position within view of the user when the eyewear body is worn; onboard electronics carried by the eyewear body including a battery carried by a first of the pair of temples; and an antenna having an active element formed by a battery flex incorporated in at least the first of the pair of temples, wherein the battery flex is a flexible electrically conductive component that extends longitudinally along at least a portion of a longitudinal length of the first of the pair of temples and couples to the battery for structural support thereof, wherein the antenna includes a metal component of the first of the pair of temples configured as a ground of the antenna.

What is claimed, is:

1. A wearable device comprising:
an eyewear body comprising:
an eyewear frame defining one or more optical element holders for holding respective optical elements within view of a user when the eyewear body is worn;
a pair of temples connected to the eyewear frame for supporting the eyewear frame in position within view of the user when the eyewear body is worn;
an antenna, comprising:
an exciter circuit,
at least a portion of a battery flex that is incorporated in a first of the pair of temples and that is configured as an active element of the antenna, and
a metal component of one of the pair of temples configured as a ground of the antenna.

2. The wearable device of claim 1, wherein the antenna includes at least one switch extending across a gap between the battery flex and the metal component, wherein the at least one switch is configured as a shorting element that selectively electrically connects the active element to the ground.

3. The wearable device of claim 2, wherein a fundamental frequency of the antenna is altered by the at least one switch being selectively opened or closed.

4. The wearable device of claim 2, wherein the at least one switch allows the antenna to be controlled to selectively operate at a first frequency range or a second frequency range.

5. The wearable device of claim 1, wherein the metal component is at least one of a temple support, a heat transfer device or a battery.

6. The wearable device of claim 5, wherein the heat transfer device is a vapor chamber, and wherein the temple support or the vapor chamber is configured as a primary ground for the antenna.

7. The wearable device of claim 1, wherein the antenna is positioned between electronics carried by the first of the pair of temples, wherein the electronics include a battery and a printed circuit board (PCB) that carries on-board communication electronics coupled to the antenna to communicate wireless signals via the antenna.

8. The wearable device of claim 7, wherein the PCB has or is coupled to a shorting bar coupled to the battery flex.

9. The wearable device of claim 7, wherein the metal component comprises a vapor chamber that extends longitudinally from the PCB at a front portion of the first of the pair of temples to the battery at a rear portion of the first of the pair of temples.

10. The wearable device of claim 1, wherein the antenna of the first of the pair of temples is configured to operate at two or more frequency ranges, and further comprising a second antenna carried by a second of the pair of temples, wherein the second antenna is configured to operate at two or more frequency ranges, wherein the two or more frequency ranges of the antenna differs from the two or more frequency ranges of the second antenna.

11. The wearable device of claim 10, wherein the antenna is configured to support at least GPS bands L1 and L5, and wherein the second antenna is configured to support at least Bluetooth band and Wi-Fi band.

12. The wearable device of claim 1, wherein the metal component is positioned between a head of the user when the eyewear body is worn and the battery flex.

13. The wearable device of claim 1, wherein the battery flex is spaced by a gap from the metal component along at least a majority of a longitudinal length thereof.

14. The wearable device of claim 13, where in the metal component is substantially continuous and extends substantially in parallel with the battery flex.

15. A method of operating an antenna in a wearable device, the method comprising:
providing an eyewear frame defining one or more optical element holders for holding respective optical elements within view of a user and a pair of temples coupled to the eyewear frame;
providing a metal component carried by a first of the pair of temples, wherein the metal component acts as a ground of the antenna;
providing a battery flex carried by the first of the pair of temples with the battery flex spaced by a gap from the metal component for a least a majority of a longitudinal length thereof, wherein the battery flex acts as an active element of the antenna; and
operating the antenna with the gap as a radiating aperture of the antenna.

16. The method of claim 15, further comprising providing at least one switch extending across the gap between the battery flex and the metal component, wherein the at least one switch is configured as a shorting element that selectively electrically connects the active element to the ground.

17. The method of claim 16, further comprising altering a fundamental frequency of the antenna by selectively opening and closing the at least one switch.

18. The method of claim 16, further comprising operating the antenna at two or more frequency ranges.

19. The method of claim 18, further comprising providing a second antenna carried by a second of the pair of temples, wherein the second antenna is configured to operate at two or more frequency ranges, wherein the two or more frequency ranges of the antenna differs from the two or more frequency ranges of the second antenna.

20. A wearable device comprising:
an eyewear body comprising:
an eyewear frame defining one or more optical element holders for holding respective optical elements within view of a user when the eyewear body is worn;
a pair of temples connected to the eyewear frame for supporting the eyewear frame in position within view of the user when the eyewear body is worn;
onboard electronics carried by the eyewear body including a battery carried by a first of the pair of temples; and
an antenna having an active element formed by a battery flex incorporated in at least the first of the pair of temples, wherein the battery flex is a flexible electrically conductive component that extends longitudinally along at least a portion of a longitudinal length of the first of the pair of temples and couples to the battery for structural support thereof, wherein the antenna includes a metal component of the first of the pair of temples configured as a ground of the antenna.
